(19) United States
(12) Patent Application Publication
(10) Pub. No.: US 2012/0007102 A1
(43) Pub. Date: Jan. 12, 2012

(54) High Voltage Device and Method for Optical Devices

(75) Inventors: Daniel Feezell, Fremont, CA (US); Rajat Sharma, Fremont, CA (US); Arpan Chakraborty, Fremont, CA (US); Troy Anthony Trottier, Fremont, CA (US); Thomas Katona, Fremont, CA (US); Mark D'Evelyn, Fremont, CA (US)

(73) Assignee: Soraa, Inc., Fremont, CA (US)

(21) Appl. No.: 13/179,346

(22) Filed: Jul. 8, 2011

Related U.S. Application Data
(60) Provisional application No. 61/362,584, filed on Jul. 8, 2010.

(51) Int. Cl. H01L 33/02

(52) U.S. Cl. 257/76; 257/103; 257/E33.023

(57) ABSTRACT

A light emitting device comprising a gallium and nitrogen containing substrate. The device also has an electrically isolating material grown between the substrate and an active region such that the light emitting device is operable at a voltage greater than 10V.

This application claims priority to U.S. Provisional Patent Application No. 61/362,584, filed Jul. 8, 2010, which is incorporated by reference herein for all purposes.

### BACKGROUND OF THE INVENTION

The present invention relates generally to lighting. Embodiments of the invention include techniques for transmitting electromagnetic radiation from LED devices, such as ultra-violet, violet, blue, blue and yellow, or blue and green. The devices may be fabricated on bulk semipolar or nonpolar materials with phosphors which emit light in a reflection mode. In other embodiments, the starting materials can include polar gallium nitride material. The invention can be applied to applications such as white lighting, multi-colored lighting, general illumination, decorative lighting, automotive and aircraft lamps, street lights, lighting for plant growth, indicator lights, lighting for flat panel displays, other optoelectronic devices, and the like.

In the late 1800's, Thomas Edison invented the light bulb. The conventional light bulb, commonly called the “Edison bulb,” has been used for over one hundred years. The conventional light bulb uses a tungsten filament enclosed in a glass bulb sealed in a base, which is screwed into a socket. The socket is coupled to an AC power or DC power source. Unfortunately the conventional light bulb dissipates more than 90% of the energy used as thermal energy. Additionally, the conventional light bulb routinely fails often due to thermal expansion and contraction of the filament element.

Solid state lighting techniques are known. Some solid state lighting relies upon semiconductor materials to produce light emitting diodes (LEDs). Red LEDs use Aluminum Indium Gallium Phosphide or AlInGaP semiconductor materials. Most recently, Shuji Nakamura pioneered the use of InGaN materials to produce LEDs emitting light in the blue color range for blue LEDs. The blue LEDs have led to innovations such as solid state white lighting, the blue laser diode and other developments. Other color LEDs have also been proposed.

High intensity UV, blue, and green LEDs based on GaN have been proposed and demonstrated with some success. Efficiencies have typically been highest in the UV-violet, dropping off as the emission wavelength increases to blue or green. Unfortunately, achieving high intensity, high-efficiency GaN-based green LEDs has been problematic. The light emission efficiency of typical GaN-based LEDs drops off significantly at higher current densities, as are required for general illumination applications, a phenomenon known as “roll-over.” Additionally, packages incorporating LEDs also have limitations. Such packages often have thermal inefficiencies, poor yields, low efficiencies, and reliability issues.

### BRIEF SUMMARY OF THE INVENTION

This invention provides a light emitting diode which includes a bulk gallium and nitrogen material having a bulk resistivity of about 0.001 ohm-cm to about 100 ohm-cm. The bulk gallium and nitrogen containing material has a surface region with electrical isolation material overlying the surface region and having an average resistivity of greater than about 1 ohm-cm. Over the isolation material an active region includes an n-type region and a p-type region to form an LED having epitaxially grown gallium and nitrogen containing material. An alternating current is coupled to the LED, preferably operable at a voltage greater than 10 volts.

The invention also provides a method for fabricating a light emitting diode device. The method includes forming isolation material on a bulk gallium and nitrogen containing substrate having an average resistivity of greater than about 1 ohm-cm. An active region is formed over the isolation material. The active region is formed with epitaxially grown gallium and nitrogen containing material and includes an n-type region and a p-type region to form LED devices.

The present device and method provides for an improved lighting technique with improved efficiencies, yet can be fabricated with conventional process equipment. In a specific embodiment, a blue LED device is capable of emitting electromagnetic radiation at a wavelength range from about 450 nanometers to about 495 nanometers and the yellow-green LED device is capable of emitting electromagnetic radiation at a wavelength range from about 495 nanometers to about 590 nanometers, although there can also be some variation.

### BRIEF DESCRIPTION OF THE DRAWINGS

FIG. 1 is a diagram of a conventional LED device with driver circuit;

FIG. 2 is a diagram of conventional rectifier devices for LED devices;

FIG. 3 is a diagram of a monolithic high voltage LED device according to an embodiment of the invention;

FIG. 4 is a diagram of a monolithic high voltage LED device according to an alternative embodiment of the invention;

FIG. 5 is a diagram of a process for fabricating a high voltage LED device according to an embodiment of the invention;

FIG. 6 is a cross-sectional view diagram of a high voltage LED device according to an embodiment of the invention;

FIG. 7 is a cross-sectional view diagram of a high voltage LED device according to an embodiment of the invention;

FIG. 8 is a diagram of a process for fabricating a high voltage LED device according to an embodiment of the invention;

FIG. 9 is a top-view diagram of a high voltage LED device according to an embodiment of the invention;

FIG. 10 is a cross-sectional diagram of a high voltage LED device according to an embodiment of the present invention;

FIG. 11 is a top view of a high voltage LED device according to an embodiment of the present invention; and

FIG. 12 is a side view of a high voltage LED device.

### DETAILED DESCRIPTION OF THE INVENTION

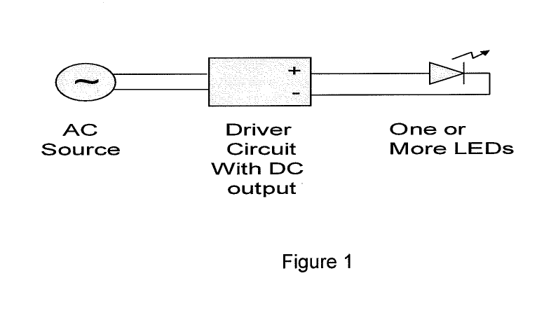

Most LED-based lamps and luminaires today incorporate a separate driver circuit which convert AC into a constant current, low voltage DC output suitable for driving the LEDs (FIG. 1). Typically this is achieved using a buck or boost circuit topology. The drawbacks associated with this method are:
1) Cost—High initial cost of LED based lighting fixtures limits their adoption. Simplification or removal of expensive components would speed market acceptance.
2) Size—A driver circuit takes up valuable space inside a light fixture. Moreover, the driver itself is a source of heat, which requires passive or active cooling. Given the limited space, the cooling element thereby has reduced capacity to cool the LED components.
3) Power Efficiency—Rated efficiencies for buck and boost converters are ˜90%, however this is for a narrow constant current range. Deviation in current output or driver temperature gives rises to decreases in driver efficiency.

Referring to FIG. 1, using the inherent rectification properties of LEDs, monolithic, driverless circuits topologies can be built into the LED chip thereby removing the need for a separate driver. Simple AC to DC bridge networks for either half-wave or full wave rectification can be used.

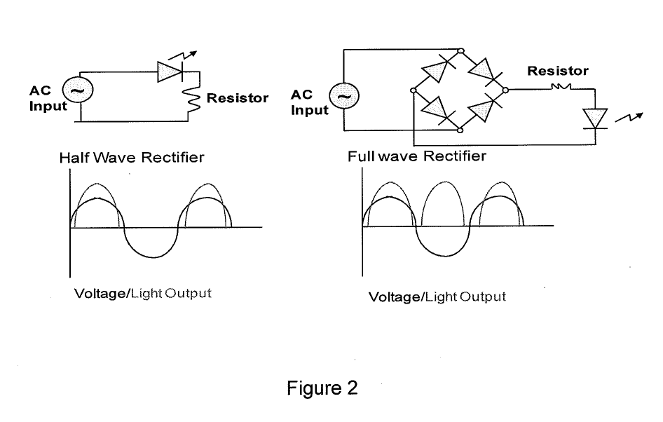

FIG. 2 depicts half wave and full wave rectifier circuits utilizing LEDs as the rectifiers and their corresponding control diagrams. Smoothing enhancements to the light output to reduce flicker can be achieved by input and output capacitive filtering. The number of LEDs used in series is limited by the peak mains voltage and the forward voltage characteristic of the LED. A series resistor is typically employed in order to limit the maximum voltage applied to the LEDs. As an example, for 110 v rms, a typical string may include 30-40 junctions in series.

High-voltage GaN-based LEDs have been described in the literature for devices grown in insulating substrates such as sapphire. However, high-voltage LEDs can also be incorporated into LEDs based on bulk GaN substrates. In these cases, the GaN substrate may be prepared with extremely high purity or compensatory doped to provide insulating properties as needed for proper device operation and isolation allowing multiple devices on a single chip. GaN substrates' inherent breakdown properties may eliminate the need for Zener protection diodes for half wave rectifying topologies.

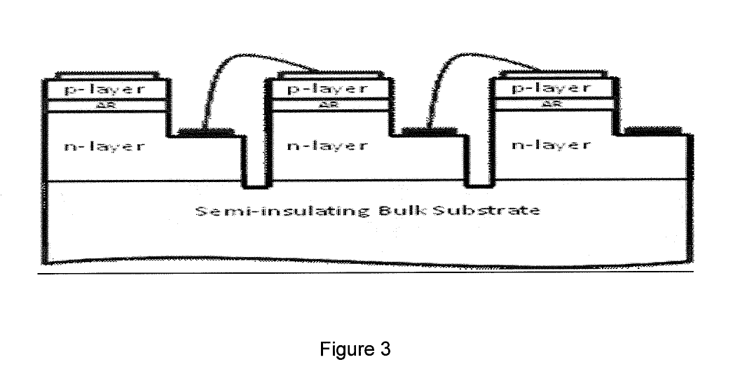

Semi-Insulating Bulk GaN Substrate. In one set of embodiments, LEDs are fabricated on a semi-insulating bulk GaN substrate, as shown schematically in FIG. 3. A semi-insulating bulk GaN substrate may be fabricated by hydride vapor phase epitaxy, as described in U.S. Pat. No. 7,170,095, which is hereby incorporated by reference in its entirety. In another specific embodiment, a semi-insulating bulk GaN substrate may be fabricated by ammonothermal crystal growth, as described in U.S. Patent Application Serial No. U.S. Provisional Application: 61/313,112, filed Mar. 11, 2010, Attorney Docket No. 027364-009400US, commonly assigned, which is hereby incorporated by reference in its entirety. In one specific embodiment, the orientation of the large-area surfaces of the semi-insulating bulk GaN substrate is within about 5 degrees, within about 2 degrees, within about 1 degree, within about 0.5 degree, within about 0.2 degree, or within about 0.1 degree of a {1 0 −1 0} m plane. In another specific embodiment, the orientation of the large-area surfaces of the seed plates is within about 5 degrees, within about 2 degrees, within about 1 degree, within about 0.5 degree, within about 0.2 degree, or within about 0.1 degree of a (0 0 0 ±1) c plane. In another specific embodiment, the orientation of the large-area surfaces of the seed plates is within about 5 degrees, within about 2 degrees, within about 1 degree, within about 0.5 degree, within about 0.2 degree, or within about 0.1 degree of a {1 1 −2 0} a plane. In some embodiments, the seed plate has a semi-polar large-surface orientation, which may be designated by (hkil) Bravais-Miller indices, where i=−(h+k), 1 is nonzero and at least one of h and k are nonzero. In a specific embodiment, the orientation of the large-area surfaces of the seed plates is within about 5 degrees, within about 2 degrees, within about 1 degree, within about 0.5 degree, within about 0.2 degree, or within about 0.1 degree of {1 −1 0 ±1}, {1 −1 0 ±2}, {1 −1 0 ±3}, {2 0 −2 ±1} or {1 1 −2 ±2}.

An ammonothermally-grown bulk GaN substrate may be characterized by a wurtzite structure substantially free from any cubic entities and have an optical absorption coefficient of about 2 cm⁻¹ and less at wavelengths between about 385 nanometers and about 750 nanometers. The ammonothermally-grown gallium nitride substrate may comprise a crystalline substrate member having a length greater than about 5 millimeters, have a wurtzite structure and be substantially free of other crystal structures, the other structures being less than about 0.1% in volume in reference to the substantially wurtzite structure, an impurity concentration greater than 10¹⁴ cm⁻³ of at least one of Li, Na, K, Rb, Cs, Mg, Ca, F, and Cl, and an optical absorption coefficient of about 2 cm⁻¹ and less at wavelengths between about 385 nanometers and about 750 nanometers. The ammonothermally-grown gallium nitride substrate may be semi-insulating, with a resistivity greater than 10⁵ Ω-cm at room temperature. The ammonothermally-grown bulk GaN substrate may be also characterized by a concentration of at one or more compensatory dopants that is less than about than 10¹⁴ cm⁻³. The compensatory dopant may be selected from at least V, Cr, Mo, W, Mn, Re, Fe, Ru, Os, Co, Rh, Ir, Ni, Pd, Pt, Cu, Ag, Au, Zn, Cd and Hg. In a preferred embodiment, the concentration of the compensatory dopant in the ammonothermally-grown bulk GaN substrate is greater than the sum of the concentrations of oxygen and silicon. The optical absorption coefficient of the ammonothermally-grown crystalline group III metal nitride at wavelengths between about 395 nm and about 460 nm may be less than about 10 cm⁻¹ depending on the embodiment.

### Isolation/Current Blocking Layers:

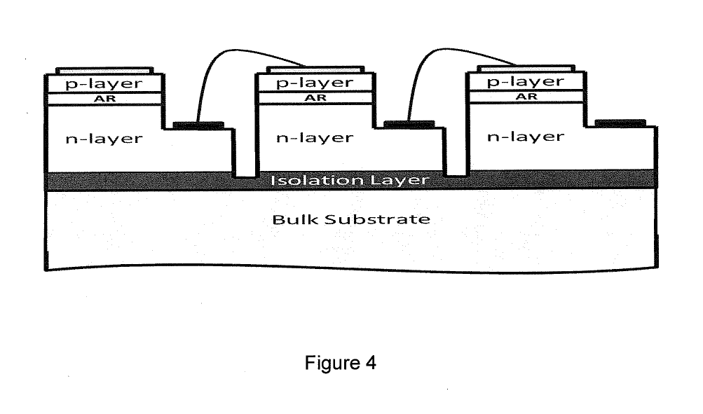

To isolate the individual LEDs on a conductive bulk GaN substrate, a current blocking layer or an isolation layer is positioned between the LED epi-structure and the bulk GaN substrate as shown in FIG. 4. This layer prevents the flow of leakage current through the substrate. The current isolation can be achieved by having an insulating layer or by having a reversed bias p-n junction diode.
1. Bulk resistivity 0.001 ohm-cm to about 0.1 ohm-cm; overlying isolation layer greater than about 100 ohm-cm; n-type active, ar, and ptype layer; voltage source alternating coupled to each of the devices.
2. The driving comprising a bridge rectifier using one or more diodes configured using the gallium nitride containing species.
3. Isolation layer is stop etch
4. Backside polishing toward stop etch layer
5. Remove bulk using stop etch
6. Roughening
7. Flip chip

The insulating layer can be formed by doping, ion-implantation, or resistive interlayer depending on the application.

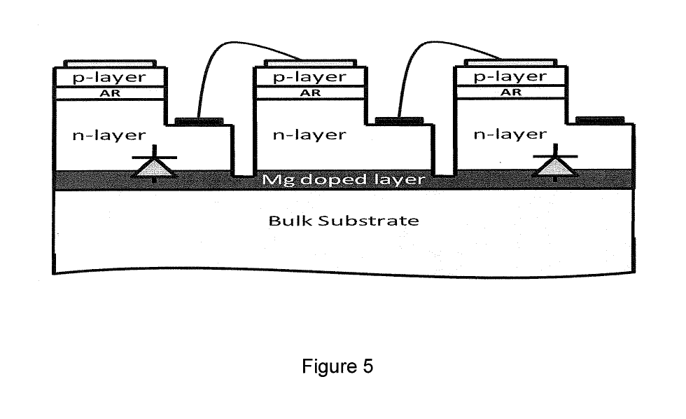

Doping
(a) The layer can be doped by heavy acceptor dopant species, at least one transitional element selected from the group of Cr, Mo, W, Mn, Re, Fe, Ru, Os, Rh, Ir, Ni, Pd, Pt, Cu, Ag, Au, Zn, Cd and Hg. Particularly preferred dopant elements include Mn, Fe, Co, Ni; and Cu and Fe being most preferred (for example, as disclosed in U.S. Pat. No. 7,170,095).
(b) The layer can be doped by impurities like C to make it insulating. Typically, C doping in MOCVD growth is achieved by growing the layer either under low pressure or at low temperature or a combination of both. Low temperature and low pressure growth leads to high C incorporation, that resulting in point defects, thereby rendering the layer insulating (Choi et al., Semicond. Sci. Technol. 22 (2007) 517-521).
(c) The layer could be doped by species like Mg, Be and Zn. Mg doped GaN layers, is usually insulating if it is not activated. If the layer is activated by annealing, the layer turns p-type in conductivity. This will create a reversed bias p-n junction diode, that will block the current from flowing vertically through the junction (as shown in the FIG. 5).

### Implantation

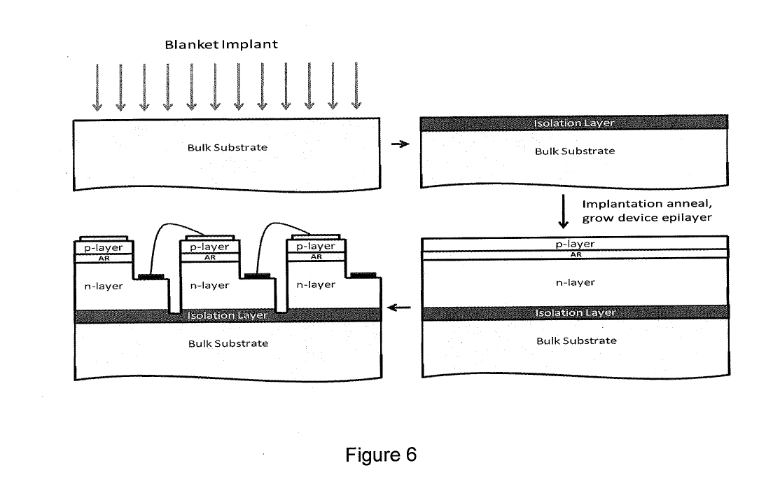

Referring to FIG. 6:
(a) The layer can be implanted with elements like Fe, Mg, Al etc to make it insulating. The implantation can be carried out on as-received bulk substrate or could be carried out on an overgrown layer. The implantation should be preferably carried out prior to the LED epi-structure re-growth to reduce any implantation damage to the active region and the p-type layers.
(b) Following the implantation, an in-situ (inside the MOCVD chamber) or ex-situ implantation anneal need to be carried out to heal the damage done to the material. The LED epi-layer is grown following the implantation anneal.

### Resistive Interlayer

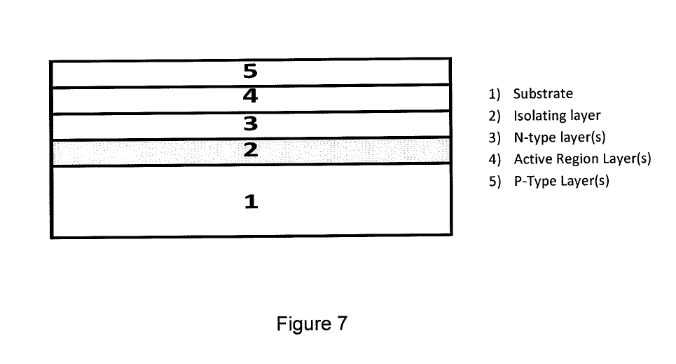

Another method for accomplishing isolation is to integrate the electrical isolation layer into part of the epitaxial growth layer sequence such that electrical isolation is provided between the substrate and the diode active region as illustrated in FIG. 7. Wide bandgap semiconductors represent an option for providing electrical isolation as they can easily be grown epitaxially on a bulk gallium nitride substrate, and also have very high breakdown fields. Table 1 shows approximate breakdown fields for these materials.

TABLE 1
Approximate Breakdown Fields For Wide Bandgap III- Nitride
Semiconductors (M. E. Levinshtein, S. L. Rumyantsev, M. S. Shur,
Properties of Advanced Semiconductor Materials:
GaN, AlN, InN, BN, SiC, SiGe, John Wiley & Sons, 2001.)

| Property | AlN | GaN | InN |
|---|---|---|---|
| Breakdown | ~1.5 × 10⁶ | ~5.0 × 10⁶ | — |
| Field (V/cm) | | | |

For AlN for instance, a thin layer of AlN (e.g. 0.1 μm) should be able to withstand at least 15 V without having breakdown. One difficulty, however, in combining electrically isolating layers into the epitaxial structure is the tendency for these layers to have a lattice mismatch with the substrate below it. AlN for example is grown in tension on bulk gallium nitride material and will crack at a critical thickness with the cracking preventing adequate electrical isolation. One method for accounting for this is to make the insulating layer or layers from a ternary or quaternary material with the composition being designed such that it is either lattice matched to the underlying layers, or is more closely lattice matched to allow for the layer to be grown to a thicker than is capable for binary materials grown on binary materials of a different type. Examples of these ternary and quaternary materials include AlₓGa₁₋ₓN, AlₓIn₁₋ₓN, AlₓGa_{y}In_{1-x-y}N where (0<x<1) and (0<y<1).

### Chips and Interconnects

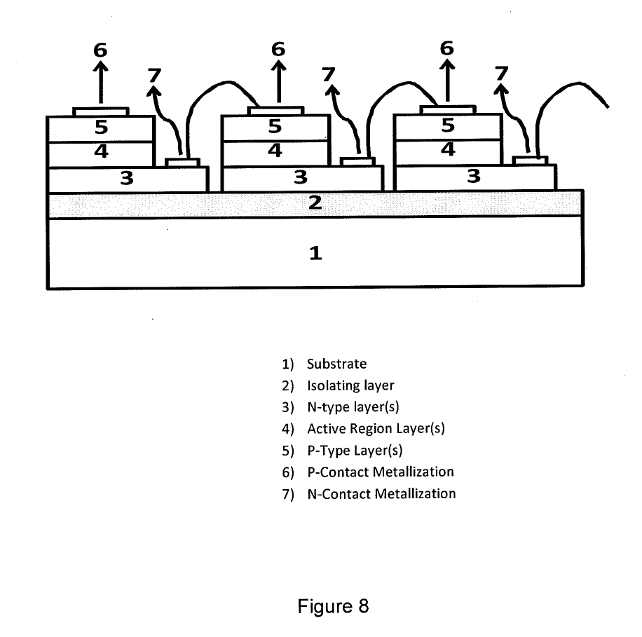

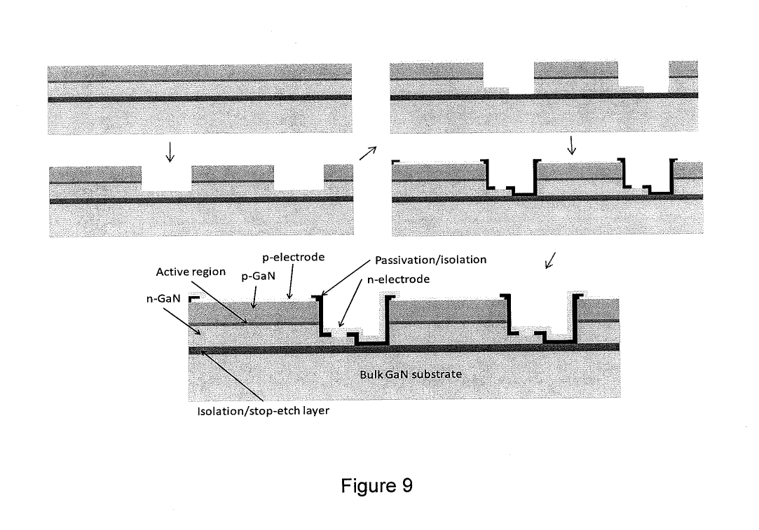

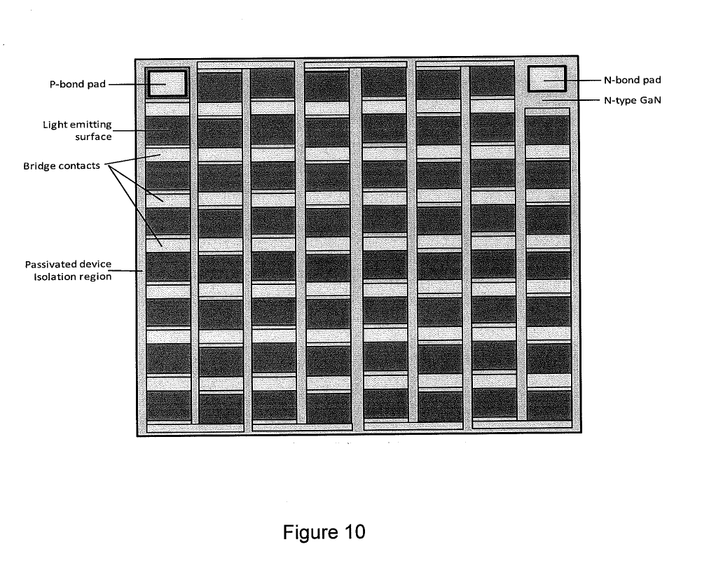

FIG. 8-9 depicts the process flow for a typical top-emitting high-voltage (HV) LED structure based on bulk GaN with the diodes connected in series. FIG. 10 shows a top-down view of the two dimensional array. Prior to processing, an epitaxial structure is deposited upon a bulk GaN substrate. This structure typically contains an isolation layer, an n-type GaN layer, an active region, and a p-type GaN layer. Initially mesa structures are formed to generate the various pixels of the interconnected LEDs. Typically, this will be achieved by utilizing RIE/ICP dry etching or photo-electrochemical (PEC) etching to etch through the active region to expose the n-GaN layer. A second etch process is then performed to expose the electrically inactive isolation layer and is necessary to prevent conduction between the n-electrodes of adjacent pixels. The isolation layer may serve as a selective stop-etch layer (the two layers may not necessarily be the same), allowing for the precise control of the n-GaN thickness. For example, the layer may be composed of AlGaN or AlN, which etch at approximately one fifth the rate of GaN. The p-electrodes are then deposited upon the mesa tops and must be substantially transparent to allow for a top-emitting device configuration. Transparency must be coupled with sufficient current spreading and is typically achieved by utilizing an indium tin oxide (ITO) layer, a thin metal layer (Ni/Au, Pt/Au, Pd/Au), or a mesh grid for the p-electrode. A second isolation (passivation) layer, which typically consists of a dielectric material such as SiO₂ or SiₓN_{y} is then deposited over the mesas. This layer isolates the interconnect metal from shorting an adjacent device and serves as a passivation mechanism for the active region sidewalls. Finally, a second metal layer is deposited to provide the n-electrode of each device and to interconnect adjacent pixels. Several common embodiments for the n-electrode are Al/Au, Al/Ni/Au, or Ti/Al/Ni/Au.

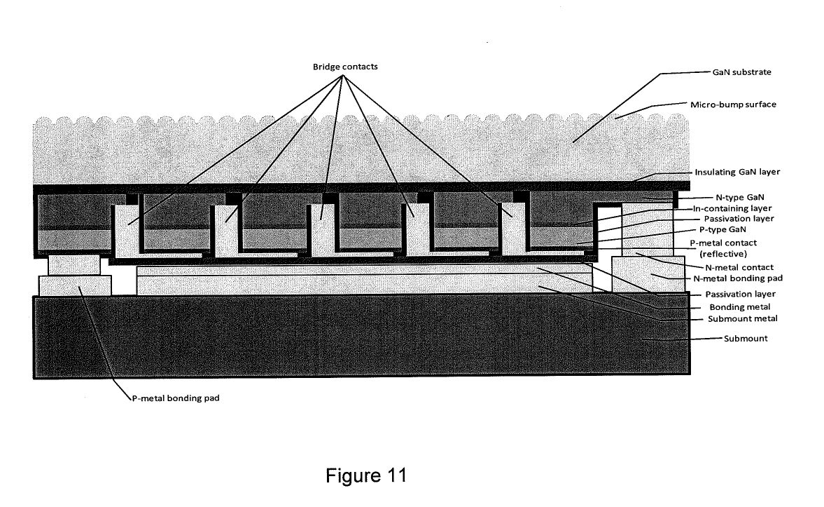

In some cases, the structure may be flipped and mounted p-side down onto a patterned submount, as shown in FIG. 11. In this configuration, only the first p-electrode and last n-electrode are electrically connected to the submount metallization. The remaining electrodes are isolated from the submount metallization by an additional passivation (dielectric) layer. The p-electrodes also serve as highly-reflective mirrors and allow for emission out of the substrate side of the structure. In the preferred embodiments, the highly reflective mirror is Ag-based or Al-based (e.g. —Pt/Ag/Ni/TiW/Ti/Au, Pt/Ag/Ni/Au, Ag/Ni/Au, Ag/TiW/Ti/Au, Ni/Ag/TiW/Ti/Au, Ni/Ag/Ni/Au, Pt/Al/Ni/TiW/Ti/Au, Pt/Al/Ni/Au, Al/Ni/Au, Al/TiW/Ti/Au, Ni/Al/TiW/Ti/Au, Ni/Al/Ni/Au, etc.). For enhanced light extraction, the bulk GaN substrate surface may be roughened by wet etching or by patterning and dry etching to form micro-bumps.

The bulk GaN substrate depicted in FIG. 9 may be thinned by chemical or mechanical lapping to produce a thin-film LED structure with a precise optical cavity thickness. In one embodiment, the substrate may be lapped to within several microns of the isolation (stop-etch) layer and then followed by an RIE/ICP dry etch or PEC etch to expose and stop on the isolation layer.

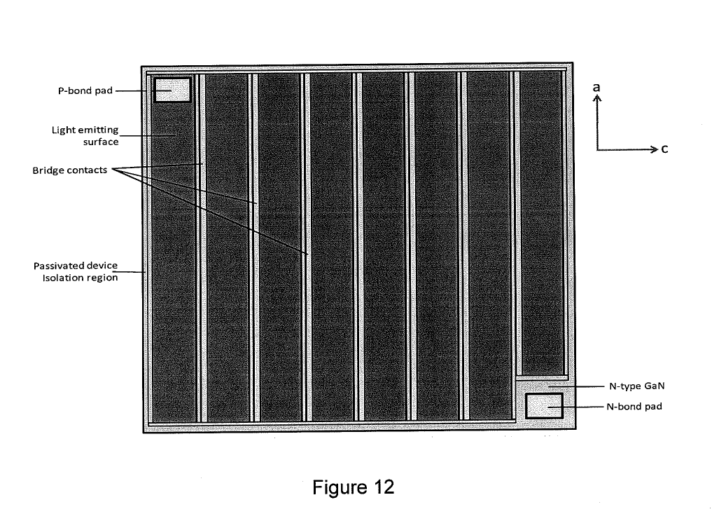

FIG. 12 depicts a top-down view of a one-dimensional interconnected HV-LED. In the preferred embodiment, the elongated mesa structures are oriented along the a-axis. Such a structure will potentially provide enhanced light extraction on nonpolar (m-plane) GaN, where the majority of emitted light propagates along the c-axis (or some projection of the c-axis). With narrow mesa structures oriented along the a-axis, the propagation length for the majority of emitted light is reduced.

While the above is a full description of the specific embodiments, various modifications, alternative constructions and equivalents may be used. As an example, the present specification describes one or more specific gallium and nitrogen containing surface orientations, but it would be recognized that any one of a plurality of family of plane orientations can be used. Of course, there can be other variations, modifications, and alternatives. Therefore, the above description and illustrations should not be taken as limiting the scope of the present invention which is defined by the appended claims.

What is claimed is:

1. A light emitting diode device comprising:
a bulk gallium and nitrogen containing substrate having a bulk resistivity of about 0.001 ohm-cm to about 100 ohm-cm, the substrate having a surface region;
electrical isolation material overlying the surface region and having an average resistivity of at least about 1 ohm-cm;
an active region of epitaxially grown gallium and nitrogen containing material over the isolation material, the active region including an n-type region and a p-type region to form at least one LED device; and
an alternating current source coupled to the at least one LED device.

2. The device of claim 1 further comprising a bridge rectifier circuit having diodes fabricated from the epitaxially grown gallium and nitrogen containing material.

3. The device of claim 1 wherein the substrate has a backside region with a roughened surface for light extraction.

4. The device of claim 1 wherein the electrical isolation material has resistivity of at least about 100 ohm-cm.

5. The device of claim 4 wherein the electrical isolation material comprises aluminum nitride.

6. The device of claim 5 wherein the electrical isolation material comprises InₓAl₁₋ₓN where (0<x<1).

7. The device of claim 5 wherein the electrical isolation material comprises InₓAl_{y}Ga_{(1-x-y)}N where (0<x<1), (0<y<1), and x+y<1.

8. The device of claim 1 wherein the electrical isolation material comprises at least one of Fe, Zn, Mg, O, and H.

9. The device of claim 7 wherein the electrical isolation material comprises a graded layer of insulating material consisting of AlₓIn_{y}Ga_{(1-x-y)}N where (0<x<1), (0<y<1), and x+y<1.

10. The device of claim 1 wherein the electrical isolation material has a thickness greater than about 10 nm.

11. A light emitting diode device comprising:
an isolation material configured from a surface of a bulk gallium and nitrogen containing material and having an average resistivity of at least about 1 ohm-cm;
an active region of epitaxially grown gallium and nitrogen containing material overlying the isolation material, the active region including an n-type region and a p-type region to form at least one LED device; and
an alternating current power supply coupled to the at least one LED device.

12. The device of claim 11 wherein the isolation material includes impurities to increase its resistivity.

13. The device of claim 12 wherein the impurities includes at least one of Fe, Zn, Mg, O, and H.

14. The device of claim 11 wherein the isolation material comprises multiple layers of insulating material consisting of AlₓIn_{y}Ga_{(1-x-y)}N where (0<x<1), (0<y<1), and x+y<1.

15. The device of claim 11 wherein the isolation material comprises a graded layer of insulating material consisting of AlₓIn_{y}Ga_{(1-x-y)}N where (0<x<1), (0<y<1), and x+y<1.
